(19) United States
(12) Patent Application Publication
(10) Pub. No.: US 2025/0218867 A1
(43) Pub. Date: Jul. 3, 2025

(54) SELECTIVE DEPOSITION OF CAPPING LAYER

(71) Applicant: Applied Materials, Inc., Santa Clara, CA (US)

(72) Inventors: Feng Q. Liu, San Jose, CA (US); Zheng Ju, Sunnyvale, CA (US); Mark Saly, Santa Clara, CA (US); Zhiyuan Wu, San Jose, CA (US); Feng Chen, San Jose, CA (US)

(73) Assignee: Applied Materials, Inc., Santa Clara, CA (US)

(21) Appl. No.: 18/400,138

(22) Filed: Dec. 29, 2023

(51) Int. Cl. H01L 21/768; H01L 21/02

(52) U.S. Cl. CPC H01L 21/76846; H01L 21/02312; H01L 21/76849; H01L 21/76898

(57) ABSTRACT

Provided are methods of forming a semiconductor device. The method includes exposing a top surface of a substrate to a reactant and a metal precursor to selectively deposit a capping layer on the top surface of the substrate, the substrate comprising at least one feature formed in a dielectric layer, the dielectric layer defining a filled gap including sidewalls and a bottom, a barrier layer on the sidewalls of the filled gap, and a metal liner on the barrier layer, the capping layer depositing on one or more of the filled gap, the barrier layer, and the metal liner.

### TECHNICAL FIELD

Embodiments of the present disclosure relate to the field of semiconductor manufacturing. More particularly, embodiments of the disclosure relate to methods of selectively depositing a metal capping layer.

### BACKGROUND

Multiple challenges impede power and performance improvements when scaling transistors and interconnects to the 3 nm node and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increase power consumption. A conventional copper interconnect structure includes a barrier layer and/or a metal liner deposited on the sidewalls of gap that provide a via the sidewalls made of a dielectric material, providing good adhesion, and preventing the copper from diffusing into the dielectric layer. A metal liner deposited on a barrier layer adheres to the barrier layer and facilitates subsequent copper (Cu) fill in a gap between the sidewalls. A cobalt capping layer is deposited on copper gap fill. The deposition of cobalt capping layer may lead to diffusion of cobalt into the metal liner (e.g., Ru liner). Moreover, cobalt may diffuse in the gap fill (e.g., copper) and decrease the gap fill conductivity.

Accordingly, there is a need for methods of depositing capping layers that improve performance of interconnects, without contaminating the metal liners and gap fills.

### SUMMARY

One or more embodiments of the present disclosure are directed to a method of forming a semiconductor device. The method comprises exposing a top surface of a substrate to a reactant and a metal precursor to selectively deposit a capping layer on the top surface of the substrate, the substrate comprising at least one feature formed in a dielectric layer, the dielectric layer defining a filled gap including sidewalls and a bottom, a barrier layer on the sidewalls of the filled gap, and a metal liner on the barrier layer, the capping layer depositing on one or more of the filled gap, the barrier layer, and the metal liner.

Additional elements of the present disclosure are directed toward a method of selectively depositing a film, the method comprises exposing a top surface of a substrate to a reactant and a metal precursor to selectively deposit capping layer on a top surface of a substrate, the substrate comprising at least one feature formed in a dielectric layer, the dielectric layer defining a filled gap including sidewalls and a bottom, the capping layer depositing on the filled gap, wherein the reactant promotes the growth rate of the capping layer on the filled gap versus the dielectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a process flow diagram of a method of forming a semiconductor device in accordance with one or more embodiments of the disclosure;

FIG. 1B illustrates a process flow diagram of a method of forming a semiconductor device in accordance with one or more embodiments of the disclosure;

FIG. 2A illustrates a cross-sectional schematic view of a semiconductor in accordance with one or more embodiments of the disclosure;

FIG. 2B illustrates a cross-sectional schematic view of a semiconductor device in accordance with one or more embodiments of the disclosure; and

FIG. 3 illustrates a cross-sectional schematic view of a semiconductor device in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas” and the like are used interchangeably to refer to any gaseous species that can react with the substrate surface, or with a film formed on the substrate surface.

In some embodiments, “selectively” means that the subject material forms on the selected surface at a rate greater than or equal to about 2×, 3×, 4×, 5×, 7×, 10×, 15×, 20×, 25×, 30×, 35×, 40×, 45× or 50× the rate of formation on the non-selected surface. Stated differently, the selectivity of the stated process for the selected surface relative to the non-selected surface is greater than or equal to about 2:1, 3:1, 4:1, 5:1, 7:1, 10:1, 15:1, 20:1, 25:1, 30:1, 35:1, 40:1, 45:1 or 50:1.

As used herein, the term “substantially free” means that there is less than about 5%, including less than about 4%, less than about 3%, less than about 2%, less than about 1%, and less than about 0.5% of halide or directly oxygen bonding metal, on an atomic basis, in the reactant or carrier gas.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A with a carrier gas, e.g., argon (Ar)) is pulsed into the reaction zone followed by a first time-delay. Next, a second precursor or compound B with a carrier gas, e.g., argon (Ar), is pulsed into the reaction zone followed by a second delay. During each time delay a purge gas, such as argon, is used to purge the reaction zone or otherwise remove any residual reactive compound or by-products from the reaction zone. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

In one or more embodiments, the formation of a film includes selective deposition of a capping layer on a top surface of a substrate.

In one or more embodiments, the formation of semiconductor devices includes selective deposition of a capping layer on the surface of a substrate. In some specific embodiments, the capping layer has a thickness in a range of from 5 Å to 25 Å. In some specific embodiments, the formation of semiconductor device includes selective deposition of a capping layer on an interconnect structure.

Current selective deposition methods are not capable of providing the desired selectivity and thinness for depositing a capping layer on a surface of an interconnect. Moreover, traditional methods induce contamination in the structure of the semiconductor device, which, in turn, deteriorates the performance of the semiconductor device. For example, in current interconnects, a cobalt (Co) capping layer may be formed on the surface of an interconnect, but the cobalt capping layer diffused along the ruthenium (Ru) liner, which can lead to undesired resistivity increases in the copper (Cu) fill.

Embodiments of the disclosure advantageously provide methods for selectively depositing a capping layer that has a high affinity for deposition on copper (Cu) not on a dielectric material, e.g., silicon oxide (SiOₓ). In one or more embodiments the semiconductor device formed according to the methods of one or more embodiments of the disclosure possesses improved overall performance.

Embodiments of the disclosure, advantageously provide methods of selectively depositing a capping layer that reduces contamination of underlying metal liners and gap fill in a semiconductor device. Interconnects comprise metal lines that transfer current within the same device layer and metal vias that transfer current between layers. Conductive materials are used to fill a gap in the via of the interconnect structure. In one or more embodiments, microelectronic devices described herein comprise at least one top interconnect structure that is interconnected to at least one bottom interconnect structure.

Embodiments of the present disclosure advantageously provide chemistries that promote the growth rate and consequent high selective deposition of a capping layer on copper (Cu) not on a dielectric material, e.g., silicon oxide (SiOₓ).

One or more embodiments provide a method of forming a semiconductor device that involves exposing a top surface of a substrate to a metal precursor and a reactant to selectively deposit a capping layer on the top surface of the substrate, the substrate comprising at least one feature formed in a dielectric layer, the dielectric layer defining a filled gap including sidewalls and a bottom, a barrier layer on the sidewalls of the filled gap, and a metal liner on the barrier layer, the capping layer depositing on one or more of the filled gap, the barrier layer, and the metal liner.

One or more embodiments provide a method for selectively depositing a film that includes exposing a top surface of a substrate to a metal precursor and a reactant to selectively deposit capping layer on a top surface of a substrate, the substrate comprising at least one feature formed in a dielectric layer, the dielectric layer defining a filled gap including sidewalls and a bottom, a barrier layer on the sidewalls of the filled gap, and a metal liner on the barrier layer, the capping layer depositing on one or more of the filled gap, the barrier layer, and the metal liner, wherein the reactant promotes the growth rate of the capping layer on one or more of the filled gap, the barrier layer, and the metal liner versus the dielectric layer. In some embodiments, the metal precursor and the reactant are deposited sequentially.

Embodiments of the present disclosure provide a chemistry (e.g., metal precursor), comprising one or more metal precursors having a general formula of L₁-M-L₂, wherein M is a metal selected from molybdenum (Mo), ruthenium (Ru), and tungsten (W), L₁ and L₂ are independently selected from aromatic, aliphatic, alkene, or carbonyl groups reacted with reactants that have a general formula of CₙHₘNₓ, wherein n is an integer in a range of from 2 to 15, m is an integer in a range of from 4 to 30, and x is an integer in a range of from 1 to 3.

Embodiments of the present disclosure advantageously provide reactants that facilitate highly selective deposition of metal films on a metal and not on a dielectric. In one or more embodiments, selective deposition is based on the native selectivity of the reactant on copper versus the dielectric material. Without intending to be bound by theory, it is thought that the reactant can help to remove ligands from a metal precursor, e.g., molybdenum precursor, to promote metal deposition. With this approach, the selectivity is defined by the native selectivity on copper from the reactant. This reactant functions as a self-assembled monolayer (SAM) to direct to the metal, e.g., molybdenum, film deposition with a higher growth rate on copper than on the dielectric. Its mechanism is explained with selective SAM promoted selective deposition on metal, e.g., molybdenum deposition. In one or more embodiments, the reactants of the present disclosure advantageously make possible the manufacture of semiconductor devices with metals (e.g., copper) that are capable of removing precursor ligands.

In some embodiments, the methods of the present disclosure are performed at a temperature in a range of from 100° C. to 500° C.

The embodiments of the disclosure are described by way of the Figures, which illustrate devices (e.g., semiconductor devices with interconnects) and processes for forming semiconductor devices in accordance with one or more embodiments of the disclosure. The processes shown are merely illustrative possible uses for the disclosed processes, and the skilled artisan will recognize that the disclosed processes are not limited to the illustrated applications.

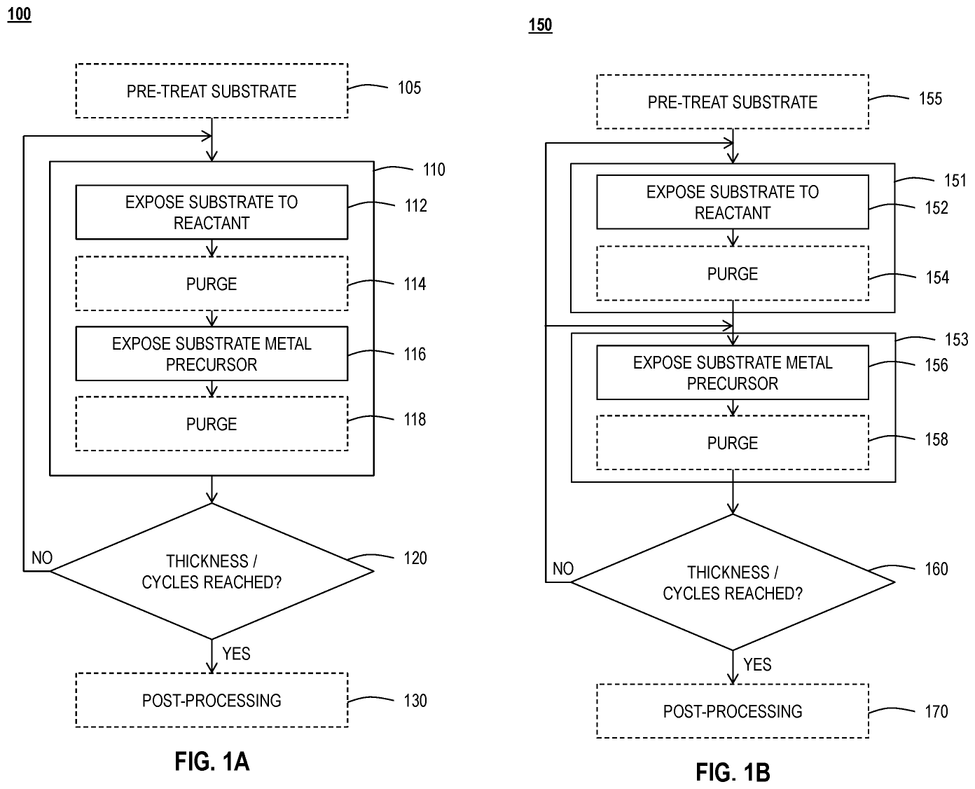

FIG. 1A illustrates a process flow diagram of a method 100 for forming a semiconductor device in accordance with one or more embodiments of the disclosure.

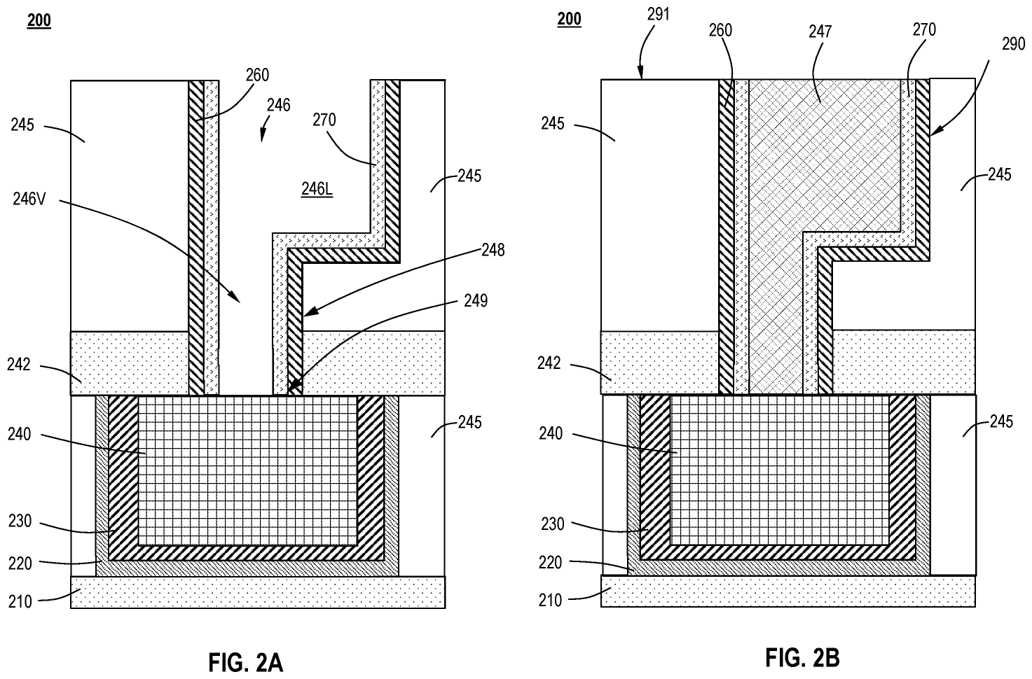

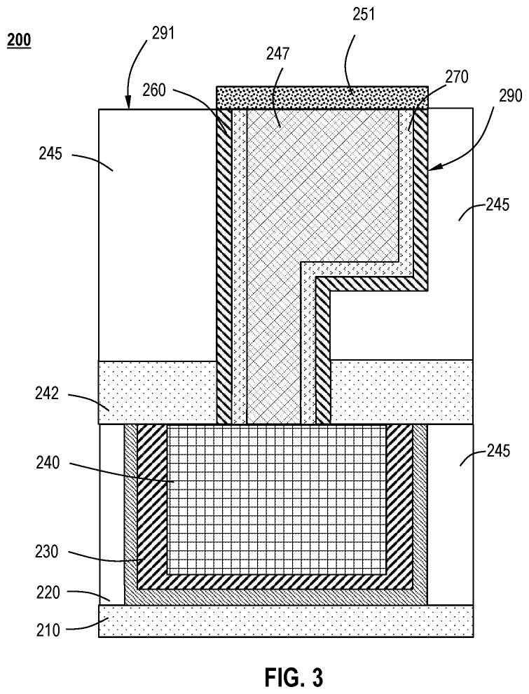

In some embodiments, the method 100 is a method of manufacturing a semiconductor device 200 as illustrated in FIGS. 2A to 3. Referring to FIGS. 2A-3, a portion of a microelectronic device 200 is shown during stages of manufacture. The semiconductor device 200 may be an intermediate structure used in the fabrication of a semiconductor device. While a particular structure of a semiconductor device is described as an example, it will be appreciated by the skilled artisan that any architecture with different designs of interconnect, may be provided in accordance with various embodiments.

In some embodiments, the method 100 is a method of forming capping layer on a substrate. The substrate may have features on a surface of the substrate on which a film is deposited with high selectivity using the method 100.

With reference to FIG. 1A, one or more embodiments of the disclosure are directed to method 100 of selectively depositing a metal film, a capping layer more particularly. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In one or more embodiments, the method comprises a chemical vapor deposition (CVD) process in which the reactive gases are mixed in the processing chamber to allow gas phase reactions of the reactive gases and deposition of the thin film.

In one or more embodiments, the method 100 includes a pre-treatment operation 105. The pre-treatment can be any suitable pre-treatment known to the skilled artisan. Suitable pre-treatments include, but are not limited to, pre-heating, cleaning, soaking, native oxide removal, or the like.

At deposition 110, a process is performed to deposit a capping layer on the substrate (or substrate surface). The deposition process 110 can include one or more operations to form the capping layer on the substrate. In operation 112, the substrate (or substrate surface) is exposed to a reactant to deposit a reactant species on the substrate (or substrate surface). The reactant can be any suitable reactant compound that can react with (i.e., adsorb or chemisorb onto) the substrate surface to leave a reactant species on the substrate surface.

At operation 114, the processing chamber is optionally purged to remove unreacted reactant, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the metal precursor by any suitable technique including, but not limited to, moving the substrate through a gas curtain to a portion or sector of the processing chamber that contains none or substantially none of the metal precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas comprises one or more of hydrogen (H₂), nitrogen (N₂), helium (He), and argon (Ar).

At operation 116, the substrate (or substrate surface) is exposed to a metal precursor to form the capping layer on the substrate. The metal precursor can react with the reactant-containing species on the substrate surface to form the capping layer.

At operation 118, the processing chamber is optionally purged after exposure to the metal precursor. Purging the processing chamber in operation 118 can be the same process or different process than the purge in operation 114. Purging the processing chamber, portion of the processing chamber, area adjacent the substrate surface, etc., removes unreacted metal precursor, reaction products, and by-products from the area adjacent the substrate surface.

At decision 120, the thickness of the deposited capping layer, or number of cycles of reactant and metal precursor is considered. If the deposited capping layer has reached a predetermined thickness or a predetermined number of process cycles have been performed, the method 100 moves to an optional post-processing operation 130. In some embodiments, the process cycle comprises sequential exposure of the substrate to the reactant, purge gas, metal precursor, and purge gas. If the thickness of the deposited film or the number of process cycles has not reached the predetermined threshold, the method 100 returns to operation 110 to expose the substrate surface to the reactant again in operation 112 and continuing.

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited capping layer. In some embodiments, the optional post-processing operation 130 comprises annealing the as-deposited capping layer. In some embodiments, annealing is done at temperatures in the range of about 300° C., 400° C., 500° C., 600° C., 700° C., 800° C., 900° C. or 1000° C.

The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the capping layer is annealed for a predetermined time in the range of about 15 seconds to about 90 minutes, or in the range of about 1 minute to about 60 minutes. In some embodiments, annealing the as-deposited capping layer increases the density, decreases the resistivity and/or increases the purity of the capping layer.

The method 100 can be performed at any suitable temperature depending on, for example, the reactant, the metal precursor, or thermal budget of the device. In one or more embodiments, the use of high temperature processing may be undesirable for temperature-sensitive substrates. In one or more embodiments, exposure to the metal precursor (operation 112) and the reactant (operation 116) occur at the same temperature. In one or more embodiments, the substrate is maintained at a temperature in a range of about 20° C. to about 400° C., or about 50° C. to about 500° C.

In one or more embodiments, exposure to the reactant (operation 112) occurs at a different temperature than the exposure to the metal precursor (operation 116). In one or more embodiments, the substrate is maintained at a first temperature in a range of about 20° C. to about 400° C., or about 50° C. to about 650° C., for the exposure to the reactant, and at a second temperature in the range of about 20° C. to about 400° C., or about 50° C. to about 650° C., for exposure the metal precursor.

In one or more embodiments, exposure of the substrate to different temperatures is facilitated by a multi-station processing platform. In one or more embodiments, the multi-station processing platform performs a spatial ALD process thereby allowing multiple substrates to be processed in different processing stations at different temperatures within the same chamber.

FIG. 1B illustrates a process flow diagram of a method 150 for forming a semiconductor device in accordance with one or more embodiments of the disclosure.

In some embodiments, the method 150 is a method of manufacturing a semiconductor device 200 as illustrated in FIGS. 2A to 3. Referring to FIGS. 2A-3, a portion of a microelectronic device 200 is shown during stages of manufacture. The semiconductor device 200 may be an intermediate structure used in the fabrication of a semiconductor device. While a particular structure of a semiconductor device is described as an example, it will be appreciated by the skilled artisan that any architecture with different designs of interconnect, may be provided in accordance with various embodiments.

In some embodiments, the method 150 is a method of forming capping layer on a substrate. The substrate may have features on a surface of the substrate on which a film is deposited with high selectivity using the method 150.

With reference to FIG. 1B, one or more embodiments of the disclosure are directed to method 150 of selectively depositing a metal film, a capping layer more particularly on a copper (Cu) surface. The method illustrated in FIG. 1B is representative of an atomic layer deposition (ALD) process in which the substrate or substrate surface is exposed sequentially to the reactive gases in a manner that prevents or minimizes gas phase reactions of the reactive gases. In one or more embodiments, the method comprises a chemical vapor deposition (CVD) process in which the reactive gases are mixed in the processing chamber to allow gas phase reactions of the reactive gases and deposition of the thin film.

In one or more embodiments, the method 150 includes a pre-treatment operation 155. The pre-treatment can be any suitable pre-treatment known to the skilled artisan. Suitable pre-treatments include, but are not limited to, pre-heating, cleaning, soaking, native oxide removal, or the like.

At deposition 151, a process is performed to deposit a reactant on the substrate (or substrate surface). The deposition process 151 can include one or more operations to deposit the reactant on the substrate. In operation 152, the substrate (or substrate surface) is exposed to a reactant to deposit a reactant species on the substrate (or substrate surface). The reactant can be any suitable reactant compound that can react with (i.e., adsorb or chemisorb onto) the substrate surface to leave a reactant-containing species on the substrate surface.

At operation 154, the processing chamber is optionally purged to remove unreacted reactant. In one or more embodiments, purging the processing chamber comprises applying a vacuum. In some embodiments, purging the processing chamber comprises flowing a purge gas over the substrate. In one or more embodiments, the purge gas comprises one or more of hydrogen (H₂), nitrogen (N₂), helium (He), and argon (Ar).

At deposit 153, a metal precursor is introduced to react with the reactant species selectively formed on the metal fill 247 surface and form a capping layer. Specifically, at operation 156 of deposition 153, the substrate (or substrate surface) is exposed to metal precursor to form the capping layer on the substrate. The metal precursor can react with the reactant species on the substrate surface to form the capping layer.

At operation 158, the processing chamber is optionally purged after exposure to the metal precursor. Purging the processing chamber in operation 158 can be the same process or different process than the purge in operation 154. Purging the processing chamber, portion of the processing chamber, area adjacent the substrate surface, etc., removes unreacted metal precursor, reaction products and by-products from the area adjacent the substrate surface.

At decision 160, the thickness of the deposited capping layer, or number of cycles of metal precursor and reactant is considered. If the deposited capping layer has reached a predetermined thickness or a predetermined number of process cycles have been performed, the method 150 moves to an optional post-processing operation 170.

In some embodiments, the process cycle comprises sequential exposure of the substrate to the reactant, purge gas, metal precursor, and purge gas. If the thickness of the deposited film or the number of process cycles has not reached the predetermined threshold, the method 150 returns to deposition 153 to expose the substrate surface to the metal precursor again in operation 156 and continuing.

In some embodiments, at deposition 153, a metal precursor is introduced pulsely to react with the reactant species selectively formed on the metal fill surface 247 and form a capping layer 251 with desired thickness on the substrate.

In some embodiments, at deposition 153, a metal precursor is introduced continuously to react with the reactant species selectively formed on the metal fill surface 247 and form a capping layer 251 with desired thickness on the substrate.

The optional post-processing operation 160 can be, for example, a process to modify film properties (e.g., annealing) or a further film deposition process (e.g., additional ALD or CVD processes) to grow additional films. In some embodiments, the optional post-processing operation 160 can be a process that modifies a property of the deposited capping layer. In some embodiments, the optional post-processing operation 160 comprises annealing the as-deposited capping layer. In some embodiments, annealing is done at temperatures in the range of about 300° C., 400° C., 500° C., 600° C., 700° C., 800° C., 900° C. or 1000° C.

The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the capping layer is annealed for a predetermined time in the range of about 15 seconds to about 90 minutes, or in the range of about 1 minute to about 60 minutes. In some embodiments, annealing the as-deposited capping layer increases the density, decreases the resistivity and/or increases the purity of the capping layer.

The method 150 can be performed at any suitable temperature depending on, for example, the metal precursor, the reactant, or thermal budget of the device. In one or more embodiments, the use of high temperature processing may be undesirable for temperature-sensitive substrates. In one or more embodiments, exposure to the reactant (operation 152) and to the metal precursor (operation 156) occur at the same temperature. In one or more embodiments, the substrate is maintained at a temperature in a range of about 20° C. to about 400° C., or about 50° C. to about 500° C.

In one or more embodiments, exposure to the reactant (operation 152) occurs at a different temperature than the exposure to the metal precursor (operation 156). In one or more embodiments, the substrate is maintained at a first temperature in a range of about 20° C. to about 400° C., or about 50° C. to about 650° C., for the exposure to the reactant, and at a second temperature in the range of about 20° C. to about 400° C., or about 50° C. to about 650° C., for exposure the metal precursor.

In one or more embodiments, exposure of the substrate to different temperatures is facilitated by a multi-station processing platform. In one or more embodiments, the multi-station processing platform performs a spatial ALD process thereby allowing multiple substrates to be processed in different processing stations at different temperatures within the same chamber.

FIGS. 2A through 3 illustrate a cross-sectional schematic views of a portion of an intermediate semiconductor device 200 being processed according to the method of one or more embodiments. With reference to FIG. 2A, an initial or starting substrate or intermediate semiconductor device 200 is provided or formed in accordance with one or more embodiments of the disclosure. As used in this specification and the appended claims, the term “provided” means that the substrate or intermediate is made available for processing (e.g., positioned in a processing chamber).

More specifically, FIG. 2A illustrates a cross-section view of the intermediate semiconductor device 200 comprising a feature defining a gap 246. The semiconductor device 200 comprises a substrate 210, a barrier layer 220 on the substrate 210, a metal liner 230 on the barrier layer 220, a conductive filled gap 240, an etch stop layer 242, a dielectric layer 245 on the etch stop layer 242, the dielectric layer 245 comprising at least one feature defining a gap 246 including sidewalls 248 and a bottom 249.

In one or more embodiments, the substrate 210 is a wafer, for example a semiconductor substrate. In one or more embodiments, the barrier layer 220 comprises any suitable barrier material known to the skilled artisan. In one or more specific embodiments, the barrier layer 220 comprises tantalum nitride (TaN). In one or more embodiments, the metal liner 230 comprises any suitable metal liner known to the skilled artisan. In one or more embodiments, the metal liner 230 comprises one or more of ruthenium (Ru), cobalt (cobalt), molybdenum (Mo), or tantalum (Ta). In one or more embodiments, the metal liner 230 comprises one or more of a single layer of ruthenium (Ru) or a single layer of cobalt (Co). In one or more embodiments, the conductive filled gap 240 may be filled with any suitable gap fill material known to the skilled artisan. In one or more embodiments, the conductive filled gap 240 comprises one or more of copper (Cu), or cobalt (Co). In one or more embodiments, the etch stop layer 242 comprises any suitable etch stop material known to the skilled artisan. In one or more embodiments, the etch stop layer 242 comprises one or more of aluminum oxide, silicon nitride and aluminum nitride.

In one or more embodiments, the dielectric layer 245 comprises any suitable dielectric material known to the skilled artisan. In one or more embodiments, the dielectric layer 245 comprises a low-k dielectric layer. In certain embodiments, the dielectric layer 245 comprises silicon oxide (SiOₓ). In one or more embodiments, the dielectric layer 245 comprises SiOₓH_{y}(CH_{z}). Further embodiments provide that the dielectric layer 245 comprises porous or carbon-doped SiOₓ. In some embodiments, the dielectric layer 245 is a porous or carbon-doped SiOₓ layer with a k value less than about 5. In other embodiments, the dielectric layer 245 is a multilayer structure. For example, in one or more embodiments, the dielectric layer 245 comprises a multilayer structure having one or more of a dielectric layer, an etch stop layer, and a hard mask layer.

In one or more embodiments, the dielectric layer 245 comprises at least one feature defining the gap 246 including sidewalls 248 and a bottom 249. The Figures show substrates having a single feature for illustrative purposes; however, those skilled in the art will understand that there can be more than one feature. The shape of the feature can be any suitable shape including, but not limited to, trenches, cylindrical vias that, when filled with metal, transfer current between layers, and lines that transfer current within the same device layer. In some embodiments, the feature defines a gap 246 in the dielectric layer 245. The gap 246 in some embodiments defines a via portion 246V and a line portion 246L, but the embodiments shown are not intended to be limiting. As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

Referring to FIGS. 2A-2B, a barrier layer 260 is shown over the sidewalls 248. In one or more embodiments, the barrier layer 260 has the same properties as the barrier layer 220. In one or more embodiments, the barrier layer 260 comprises any suitable barrier material known to the skilled artisan. In one or more specific embodiments, the barrier layer 260 comprises tantalum nitride (TaN). In one or more embodiments, the barrier layer 260 does not form on the bottom 249 of the gap 246. In one or more embodiments, the deposition of the barrier layer 260 is substantially conformal. As used herein, a layer which is “substantially conformal” refers to a layer where the thickness is about the same throughout (e.g., on the top, middle, and bottom of sidewalls 248 and on the bottom 249 of the gap 246). A layer which is substantially conformal varies in thickness by less than or equal to about 5%, 2%, 1%, or 0.5%. In one or more embodiments, the barrier layer 260 may cover the entirety of the sidewalls 248.

In one or more embodiments, the barrier layer 260 is selectively deposited by atomic layer deposition (ALD), and has a thickness in a range of from about 2 Å to about 10 Å. In some embodiments, the barrier layer 260 is deposited in a single ALD cycle. In other embodiments, the barrier layer 260 is deposited in from 1 to 20 ALD cycles. In one or more embodiments, each cycle of the 1 to 20 ALD cycles is configured to deposit a thickness of about 0.5 Å of the barrier layer 260.

FIG. 2B illustrates a cross-sectional schematic view of a portion of the intermediate semiconductor device 200 comprising an interconnect 290 with a filled gap 247. In one or more embodiments, a bottom-up gapfill process may be used to fill the feature 246 from the bottom versus a conformal process which fills the feature 246 from the bottom and sides to form a filled gap 247. In other embodiments, a conformal process may be used to fill the feature 246 with a gap fill material to form a filled gap 247. The gap fill material may comprise any suitable gap fill material known to the skilled artisan. According to some embodiments, the filled gap 247 comprises one or more of copper (Cu), manganese (Mn), or cobalt (Co). In one or more specific embodiments, the filled gap 247 comprises copper (Cu) and manganese (Mn).

FIG. 3 illustrates a cross-sectional schematic view of a portion of the semiconductor device 200 having a capping layer 251 thereon. In one or more embodiments, the capping layer 251 has a thickness in a range of from 5 to 25 Å, including in a range of from 10 Å to 20 Å.

With reference to FIG. 1A and FIG. 3, at operation 112, the top surface 291 of the substrate 200 is exposed to a reactant and a metal precursor to selectively deposit the capping layer 251 on the filled gap 247, on the barrier layer 260, on the metal liner 270, and not on the dielectric layer 245. As will be appreciated by one of skill in the art, in one or more embodiments, the substrate may be first exposed to the reactant then subsequently be exposed to the metal precursor to form the capping layer 251. In other embodiments, however, the substrate may be first exposed to the metal precursor and then subsequently be exposed to the reactant to form the capping layer 251. Regardless, the deposition 110 of method 100 can be described as exposing the substrate (or substrate surface) to a reactant and a metal precursor.

With reference to FIG. 1B and FIG. 3, at deposition 151 and deposition 153, the top surface 291 of the substrate 200 is exposed to a reactant and a metal precursor to selectively deposit the capping layer 251 on the filled gap 247, on the barrier layer 260, on the metal liner 270, and not on the dielectric layer 245. As will be appreciated by one of skill in the art, in one or more embodiments, the substrate may be first exposed to the reactant then subsequently be exposed to the metal precursor to form the capping layer 251. In other embodiments, however, the substrate may be first exposed to the metal precursor and then subsequently be exposed to the reactant to form the capping layer 251. Regardless, the deposition 151,153 of method 150 can be described as exposing the substrate (or substrate surface) to a reactant and a metal precursor.

One or more embodiments of the present disclosure utilize SAM chemistries that advantageously provide highly selective deposition of the capping layer 251 on the filled gap 247, on the barrier layer 260, and on the metal liner 270 over the dielectric layer 245 by promoting the growth rate of metal (e.g., copper or cobalt) over a dielectric material (e.g., SiO₂). In one or more embodiments, the capping layer 251 is a self-assembled monolayer (SAM). In one or more embodiments, the filled gap 247, the barrier layer 260, and the metal liner 270 independently comprise one or more of copper (Cu), ruthenium (Ru), cobalt (Co), molybdenum (Mo), tungsten (W), and tantalum nitride (TaN). Embodiments of the present disclosure advantageously make possible the deposition of the capping layer 251 on the substrate surface 291 without contaminating the gap fill 247, the barrier layer 260, and the metal liner 270, and without consequently comprising or reducing the conductivity of the interconnect.

Referring to FIG. 1A and FIG. 2B, at operation 112, the substrate (or substrate surface) is exposed to a reactant to form a reactant species on the substrate, specifically, on one or more of the filled gap 247, on the metal liner 270, and on the barrier layer 260, but not on the dielectric layer 245. The reactant can be any suitable reactant that can react with one or more of the filled gap 247, the metal liner 270, and the barrier layer 260 to form a reactant species on the substrate surface.

Referring to FIG. 1B and FIG. 2B, at operation 152, the substrate (or substrate surface) is exposed to a reactant to form a reactant species on the substrate, specifically, on one or more of the filled gap 247, on the metal liner 270, and on the barrier layer 260, but not on the dielectric layer 245. The reactant can be any suitable reactant that can react with one or more of the filled gap 247, the metal liner 270, and the barrier layer 260 to form a reactant species on the substrate surface.

In one or more embodiments, the reactant has a general formula of CₙHₘNₓ, wherein n is an integer in a range of from 2 to 15, m is an integer in a range of from 4 to 30, and x is an integer in a range of from 1 to 3. In one or more embodiments, the reactant comprises one or more of amines and imines.

In one or more embodiments, the reactant comprises one or more of alkyl amine, alkyl imine, pyrrole, imidazole, pyrazole, triazole, trimethylamine, triethylamine, tripropylamine, 1,2,3-triazole, 1,2,4-triazole, benzotriazole, and 1,4,-diazabicyclo[2.2.2.]octane, pyrazine, or a derivative thereof.

Referring to FIG. 1A and FIG. 2B, at operation 152, the substrate (or substrate surface) is exposed to a metal precursor to form a capping layer 251 on the substrate, specifically, on one or more of the filled gap 247, on the metal liner 270, and on the barrier layer 260, but not on the dielectric layer 245. The metal precursor can be any suitable metal precursor that can react with the reactant species formed on the substrate surface.

Referring to FIG. 1B and FIG. 2B, at operation 156, the substrate (or substrate surface) is exposed to a metal precursor to form a capping layer 251 on the substrate, specifically, on one or more of the filled gap 247, on the metal liner 270, and on the barrier layer 260, but not on the dielectric layer 245. The metal precursor can be any suitable metal precursor that can react with the reactant species formed on the substrate surface.

Metal (M) containing films can be formed by atomic layer deposition or chemical vapor deposition for many semiconductor applications. One or more embodiments of the disclosure advantageously provide processes for atomic layer deposition or chemical vapor deposition to form metal-containing capping layers on a semiconductor device. As used in this specification and the appended claims, the term “metal-containing film” refers to a film that comprises metal atoms and has greater than or equal to about 1 atomic % metal, greater than or equal to about 2 atomic % metal, greater than or equal to about 3 atomic % metal, greater than or equal to about 4 atomic % metal, greater than or equal to about 5 atomic % metal, greater than or equal to about 10 atomic % metal, greater than or equal to about 15 atomic % metal, greater than or equal to about 20 atomic % metal, greater than or equal to about 25 atomic % metal, greater than or equal to about 30 atomic % metal, greater than or equal to about 35 atomic % metal, greater than or equal to about 40 atomic % metal, greater than or equal to about 45 atomic % metal, greater than or equal to about 50 atomic % metal, or greater than or equal to about 60 atomic % metal. In one or more embodiments, the metal, M, is a metal selected from molybdenum (Mo), ruthenium (Ru), and tungsten (W). Thus, in one or more embodiments, the capping layer 251 comprises one or more of molybdenum (Mo), ruthenium (Ru), and tungsten (W).

In some embodiments, the metal-containing film comprises one or more of metal (elemental metal), metal carbide (MCₓ), metal carbonitride (MCₓN_{y}), metal silicide (MSiₓ), metal carbosilicide (MCₓSi_{y}), metal sulfide (MSₓ), metal carbosulfide (MCₓS_{y}), metal nitride (MNₓ), metal phosphide (MoPₓ), or metal carbophosphide (MoCₓP_{y}).

The skilled artisan will recognize that the use of molecular formula, e.g., metal carbide (MCₓ), metal carbonitride (MCₓN_{y}), metal silicide (MSiₓ), metal carbosilicide (MCₓSi_{y}), metal sulfide (MSₓ), metal carbosulfide (MCₓS_{y}), metal nitride (MNₓ), metal phosphide (MoPₓ), or metal carbophosphide (MoCₓP_{y}) does not imply a specific stoichiometric relationship between the elements but merely the identity of the major components of the film. For example, MCₓ refers to a film whose major composition comprises metal (M) atoms and carbon (C) atoms. In some embodiments, the major composition of the specified film (i.e., the sum of the atomic percent of the specified atoms) is greater than or equal to about 95%, 98%, 99% or 99.5% of the film, on an atomic basis.

In one or more embodiments, the metal precursor has a general formula of L₁-M-L₂, wherein M is a metal selected from molybdenum (Mo), ruthenium (Ru), and tungsten (W), L₁ and L₂ are independently selected from aromatic, aliphatic, alkene, or carbonyl groups. In some embodiments, L₁ and L₂ can be the same. In other embodiments, L₁ and L₂ are different. Without intending to be bound by theory, it is thought that the presence of halides in the structure of the metal precursor can pose challenges, as halide contamination may affect device performance and hence require additional removal procedures. Halides bind strongly to metals, requiring higher thermal budget, or the use of additional reagents for its removal. Additionally, halide can redeposit and poison other metal surfaces. Accordingly, in one or more embodiments, the metal precursor is halide free and directly oxygen bonding free. In one or more embodiments, the metal precursor is substantially free of halide and metal halides. In one or more embodiments, the metal precursor is halide free and oxygen free and has a general formula of L₁-M-L₂.

As used herein, the term “directly oxygen bonding free” means that the elemental metal of the metal precursor is not bonded to the oxygen atom(s) in the ligands bonding to the elemental metal. For example, in Mo(CO)₆, molybdenum is not directly bonded to oxygen atoms of the carboxyl group (CO).

As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—).

Unless otherwise indicated, the term “lower alkyl,” “alkyl,” or “alk” as used herein alone or as part of another group includes both straight and branched chain hydrocarbons, containing 1 to 20 carbons, or 1 to 10 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

In one or more embodiments, the metal precursor comprises one or more of Mo(CO)₆, W(CO)₆, Ru₃(CO)₁₂, molybdenum hexacarbonyl, and (cycloheptatriene)Mo(CO), and (arene)molybdenum derivatives. In one or more embodiments, the (arene) molybdenum derivative comprises one or more of (trimethylbenzene)Mo(CO)₃, bis(methylbenzene)Mo, bis(ethylbenzene)Mo, bis(4-isopropyltoluene)Mo, and bis(benzene)Mo.

In one or more embodiments, the metal precursor may be carried in one or more carrier gas. The carrier gas may comprise any suitable carrier gas known to the skilled artisan. In one or more embodiments, the carrier gas comprises one or more of hydrogen (H₂), argon (Ar), and the like.

According to one or more embodiments, the substrate is subjected to processing prior to and/or after forming the capping layer. This processing can be performed in the same chamber or in one or more separate processing chambers. In one or more embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at the front end of the cluster tool. The exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In one or more embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrate are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In one or more embodiments, the substrate support includes a heater/cooler which can be controlled to change the substrate temperature conductively. In one or more embodiments, the gases (either reactive gases or inert gases) being employed are heated or cooled to locally change the substrate temperature. In one or more embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Deposition of Molybdenum-Containing Capping Layer

General procedure: A substrate comprising copper (Cu) and manganese (Mn) was placed in a processing chamber. The substrate was treated with triazole gas for about 1 second. Unreacted triazole and byproducts were then purged out of the chamber with a 50 second purge. The substrate was then exposed to a molybdenum precursor carried in an atmosphere of H₂ gas for about 1.2 seconds. Excess metal precursor and byproducts were removed from the chamber by purging for 20 seconds. The deposition cycle was repeated about 50 times to form a molybdenum-containing capping layer on the substrate with a selectivity growth rate of more than 2:1 over the dielectric layer, silicon oxide (SiO₂). The deposition occurred at a temperature in a range of from 150° to 310° C.

Spatially relative terms, such as “beneath,” “below,” “lower,” “above,” “upper”, “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor device, the method comprising:
exposing a top surface of a substrate to a reactant and a metal precursor to selectively deposit a capping layer on the top surface of the substrate, the substrate comprising at least one feature formed in a dielectric layer, the dielectric layer defining a filled gap including sidewalls and a bottom, a barrier layer on the sidewalls of the filled gap, and a metal liner on the barrier layer, the capping layer depositing on one or more of the filled gap, the barrier layer, and the metal liner.

2. The method of claim 1, wherein the capping layer has a thickness in a range of from 5 Å to 25 Å.

3. The method of claim 1, wherein the reactant has a general formula of CₙHₘNₓ, wherein n is an integer in a range of from 2 to 15, m is an integer in a range of from 4 to 30, and x is an integer in a range of from 1 to 3.

4. The method of claim 3, wherein the reactant comprises one or more of alkyl amine, alkyl imine, pyrrole, imidazole, pyrazole, triazole, trimethylamine, triethylamine, tripropylamine, 1,2,3-triazole, 1,2,4-triazole, benzotriazole, and 1,4,-diazabicyclo[2.2.2.]octane, pyrazine, or a derivative thereof.

5. The method of claim 1, wherein the filled gap, the barrier layer, and the metal liner independently comprise one or more of copper (Cu), ruthenium (Ru), manganese (Mn), cobalt (Co), molybdenum (Mo), tungsten (W), and tantalum nitride (TaN).

6. The method of claim 1, wherein the capping layer comprises one or more of molybdenum (Mo), ruthenium (Ru), and tungsten (W).

7. The method of claim 1, wherein the metal precursor is substantially halide free and directly oxygen bonding free.

8. The method of claim 7, wherein the metal precursor has a general formula of L₁-M-L₂, wherein M is a metal selected from molybdenum (Mo), ruthenium (Ru), and tungsten (W), L₁ and L₂ are independently selected from aromatic, aliphatic, alkene, or carbonyl groups.

9. The method of claim 8, wherein the metal precursor comprises one or more of Mo(CO)₆, W(CO)₆, Ru₃(CO)₁₂, molybdenum hexacarbonyl, (cycloheptatriene)Mo(CO), and (arene)molybdenum derivative.

10. The method of claim 9, wherein the (arene) molybdenum derivative comprises one or more of (trimethylbenzene)Mo(CO)₃, bis(methylbenzene)Mo, bis(ethylbenzene)Mo, bis(4-isopropyltoluene)Mo, and bis(benzene)Mo.

11. The method of claim 1, wherein the filled gap comprises copper (Cu) and manganese (Mn), the barrier layer comprises tantalum nitride (TaN), and the metal liner comprises one or more of cobalt (Co) and ruthenium (Ru).

12. A method for selectively depositing a film, the method comprising:
exposing a top surface of a substrate to a reactant and a metal precursor to selectively deposit capping layer on a top surface of a substrate, the substrate comprising at least one feature formed in a dielectric layer, the dielectric layer defining a filled gap including sidewalls and a bottom, the capping layer depositing on the filled gap, wherein the reactant promotes the growth rate of the capping layer on the filled gap versus the dielectric layer.

13. The method of claim 11, wherein the reactant has a general formula of CₙHₘNₓ, wherein n is an integer in a range of from 2 to 15, m is an integer in a range of from 4 to 30, and x is an integer in a range of from 1 to 3.

14. The method of claim 12, wherein the reactant comprises one or more of alkyl amine, alkyl imine, pyrrole, imidazole, pyrazole, triazole, trimethylamine, triethylamine, tripropylamine, 1,2,3-triazole, 1,2,4-triazole, benzotriazole, and 1,4,-diazabicyclo[2.2.2.]octane, pyrazine, or a derivative thereof.

15. The method of claim 11, wherein the filled gap comprises one or more of copper (Cu), ruthenium (Ru), manganese (Mn), cobalt (Co), molybdenum (Mo), tungsten (W), and tantalum nitride (TaN).

16. The method of claim 12, further comprising a barrier layer on the sidewalls of the filled gap, and a metal liner on the barrier layer.

17. The method of claim 12, wherein the capping layer comprises one or more of molybdenum (Mo), ruthenium (Ru), and tungsten (W).

18. The method of claim 11, wherein the metal precursor is halide free and oxygen free and has a general formula of L₁-M-L₂, wherein M is a metal selected from molybdenum (Mo), ruthenium (Ru), and tungsten (W), L₁ and L₂ are independently selected from aromatic, aliphatic, alkene, or carbonyl groups.

19. The method of claim 18, wherein the metal precursor comprises one or more of Mo(CO)₆, W(CO)₆, Ru₃(CO)₁₂, molybdenum hexacarbonyl, (cycloheptatriene)Mo(CO), and (arene)molybdenum derivative.

20. The method of claim 19, wherein the (arene) molybdenum derivative comprises one or more of (trimethylbenzene)Mo(CO)₃, bis(methylbenzene)Mo, bis(ethylbenzene)Mo, bis(4-isopropyltoluene)Mo, and bis(benzene)Mo.
